(19) United States
(12) Patent Application Publication
(10) Pub. No.: US 2026/0230043 A1
(43) Pub. Date: Aug. 6, 2026

(54) VOLTAGE REFERENCE CURRENT BOOST CIRCUIT

(71) Applicant: Texas Instruments Incorporated, Dallas, TX (US)

(72) Inventors: Mark Allan SHILL, Tucson, AZ (US); Keith Charles BROUSE, Vail, AZ (US)

(73) Assignee: Texas Instruments Incorporated, Dallas, TX (US)

(21) Appl. No.: 19/042,831

(22) Filed: Jan. 31, 2025

(51) Int. Cl. H03F 1/34; G05F 1/625; H03M 1/66

(52) U.S. Cl. CPC H03F 1/34; G05F 1/625; H03M 1/66; H03F 2200/186

(57) ABSTRACT

An apparatus includes an amplifier and a current source. The amplifier has a voltage reference input, a second input, an output, and a terminal coupled to a supply voltage terminal. The current source has an input coupled to the output of the amplifier, a first output coupled to the second input of the amplifier, a second output coupled to the voltage reference input of the amplifier, and a terminal coupled to the supply voltage terminal.

### BACKGROUND

Voltage reference circuits are used in a wide variety of electronic devices to provide an output voltage (a reference voltage) that is constant across the operational conditions of the device. For example, a voltage reference circuit may provide an output voltage that is constant over a wide range of temperature and load conditions. A digital-to analog converter (DAC) is one example of an electronic device that uses a voltage reference circuit. In a DAC, the analog output voltage may be derived from the reference voltage provided by the voltage reference circuit.

### SUMMARY

In one example, an apparatus includes an amplifier and a current source. The amplifier has a voltage reference input, a second input, an output, and a terminal coupled to a supply voltage terminal. The current source has an input coupled to the output of the amplifier, a first output coupled to the second input of the amplifier, a second output coupled to the voltage reference input of the amplifier, and a terminal coupled to the supply voltage terminal.

In another example, an apparatus includes an amplifier and a current source. The amplifier has a voltage reference input, a second input, an output, and a terminal coupled to a supply voltage terminal. The current source includes a first transistor and a second transistor. The first transistor has a first a first terminal coupled to the supply voltage terminal, a second terminal coupled to the second terminal of the amplifier, and a control terminal coupled to the output of the amplifier. The second transistor has a first terminal coupled to the supply voltage terminal, a second terminal coupled to the voltage reference input of the amplifier, and a control terminal coupled to the output of the amplifier.

In a further example, a system includes a digital-to-analog converter (DAC) and a current boost circuit. The DAC has a reference input. The current boost circuit includes an amplifier, a resistor, and a current source. The amplifier has a voltage reference input, a second input, an output, and a terminal coupled to a supply voltage terminal. The resistor has a first terminal coupled to the second input of the amplifier, and a second terminal coupled to a reference terminal. The current source includes a first transistor and a second transistor. The first transistor has a first terminal coupled to the supply voltage terminal, a second terminal coupled to the second input of the amplifier, and a control terminal coupled to the output of the amplifier. The second transistor has a first terminal coupled to the supply voltage terminal, a second terminal coupled to the voltage reference input of the amplifier and the reference input of the DAC, and a control terminal coupled to the output of the amplifier.

### BRIEF DESCRIPTION OF THE DRAWINGS

FIG. 1 is a block diagram of an example current boost circuit suitable for use with a voltage reference circuit.

FIG. 2 is a schematic diagram of an example current source suitable for use in the current boost circuit of FIG. 1.

FIG. 3 is a block diagram of an example current boost circuit with variable current output suitable for use with a voltage reference circuit.

FIG. 4 is a schematic diagram of an example current source with variable current output suitable for use in the current boost circuit of FIG. 3.

FIG. 5 is a block diagram of an example system that uses the current boost circuit of FIG. 1 to boost the current of a reference voltage provided to multiple digital-to-analog converters from a voltage reference circuit.

FIG. 6 is a block diagram of an example system that uses the current boost circuit of FIG. 3 to boost the current of a reference voltage provided to multiple digital-to-analog converters from a voltage reference circuit.

### DETAILED DESCRIPTION

In some applications, a load circuit may draw more current than is desirable from a reference voltage source. For example, a voltage reference circuit may be configured to provide a reference voltage limited to a few hundred micro-amperes of current, and a load circuit coupled to the voltage reference may draw milli-amperes of current from the reference voltage source. In such applications, the load circuit may include a buffer amplifier coupled between an output the reference voltage source and an input of the load circuit to reduce loading. However, the buffer amplifier can introduce noise and drift that may degrade the operation of the load circuit. For example, the load circuit may include one or more digital-to-analog converters (DACs), the output of which may be degraded by noise or drift introduced by a buffer amplifier applied in the reference voltage path.

The current boost circuits described herein provide current that reduces loading of the reference voltage source without introducing noise or drift. The current boost circuits can significantly reduce reference voltage source loading in a wide variety of applications.

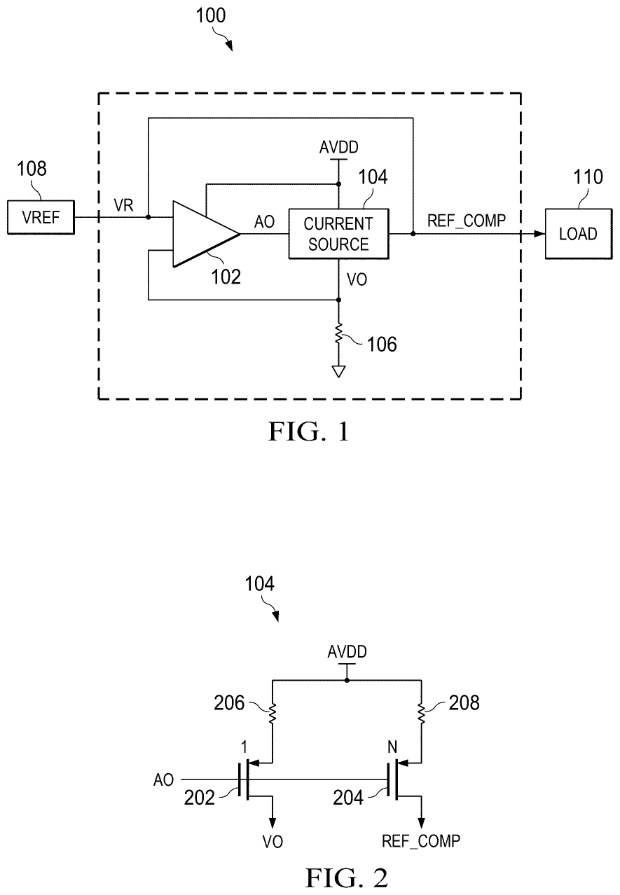

FIG. 1 is a block diagram of an example current boost circuit 100. The current boost circuit 100 includes an amplifier 102 and a current source 104. The amplifier 102 has first and second inputs and an output. The first input (e.g., a non-inverting input) can be coupled to an output of a voltage reference circuit 108. The first input of the amplifier is thus referred to as a voltage reference terminal. The second input (e.g., an inverting input) is coupled to the current source 104, and the output is coupled to the current source 104. The amplifier 102 controls the current source 104 based on the reference voltage (VR) provided by the voltage reference circuit 108. The current source 104 has a voltage terminal that is coupled to a power terminal (AVDD) (also referred to as a supply voltage terminal) at which a power supply voltage is provided. The current source 104 draws current from AVDD to support VR provided to a load circuit 110. In some examples, the current boost circuit 100 and the load circuit 110 may be provided on a same integrated circuit, and in other examples on different integrated circuits. The voltage reference circuit 108 may be coupled to the current boost circuit 100 and the load circuit 110 using at least one terminal (e.g., a pin, pad, lead, etc.) of the integrated circuit.

The current source 104 has an input and first and second outputs. The input is coupled to the output of the amplifier 102 for receipt of amplifier output signal AO. The first output is coupled to the second input of the amplifier 102. The second output coupled to a reference voltage input of the load circuit 110 and to the first input of the amplifier 102 (to the output of the voltage reference circuit 108). A resistor 106 has a first terminal coupled to the first output of the current source 104, and a second terminal coupled to a reference terminal at which is provided a voltage less than the power supply voltage at AVDD (e.g., ground). The current source 104 provides a first current at the first output, as signal VO. The first current provided at the first output of the current source 104 flows through the resistor 106. The amplifier 102 causes the voltage across the resistor 106 to be the same as the voltage VR provided by the voltage reference circuit 108. The resistance of the resistor 106 may be selected to draw a quantity of the first current equal to a selected fraction of the current drawn at the reference voltage input of the load circuit 110.

The current source 104 provides a current (REF_COMP) at its second output. REF_COMP may be a selected multiple of the current provided at the first output of the current source 104. For example, REF_COMP may be selected to equal the current drawn at the reference voltage input of the load circuit 110. The voltage reference circuit 108 controls the voltage at the second output of the current source 104. The current drawn by the reference voltage input of the load circuit 110 is provided, in large part or in whole, by the current source 104. Accordingly, the current boost circuit 100 can significantly reduce the current drawn from the voltage reference circuit 108.

FIG. 2 is a schematic diagram of an example current source 104. The current source 104 includes a transistor 202, a transistor 204, a resistor 206, and a resistor 208. The transistor 202 and the transistor 204 may be p-channel field effect transistors (PFETs). The transistor 202 and the transistor 204 may be sized such that the transistor 204 is N times larger than the transistor 202 (e.g., the channel width of the transistor 204 may N times greater than the channel width of the transistor 202). The transistor 202 has a first terminal (e.g., source) coupled to AVDD by the resistor 206. The resistor 206 has a first terminal coupled to AVDD and a second terminal coupled to the first terminal of the transistor 202. The transistor 202 has a second terminal (e.g., drain) that serves as the first output of the current source 104. VO is provided at the second terminal of the transistor 202. The transistor 202 has a control terminal (e.g., gate) coupled to the output of the amplifier 102.

The transistor 204 has a first terminal (e.g., source) coupled to AVDD by the resistor 208. The resistor 208 has a first terminal coupled to AVDD and a second terminal coupled to the first terminal of the transistor 204. The transistor 204 has a second terminal (e.g., drain) that serves as the second output of the current source 104. REF_COMP is provided at the second terminal of the transistor 204. The transistor 204 has a control terminal (e.g., gate) coupled to the output of the amplifier 102. In accordance with the sizing of the transistors 202 and 204, REF_COMP current may be multiple of VO current.

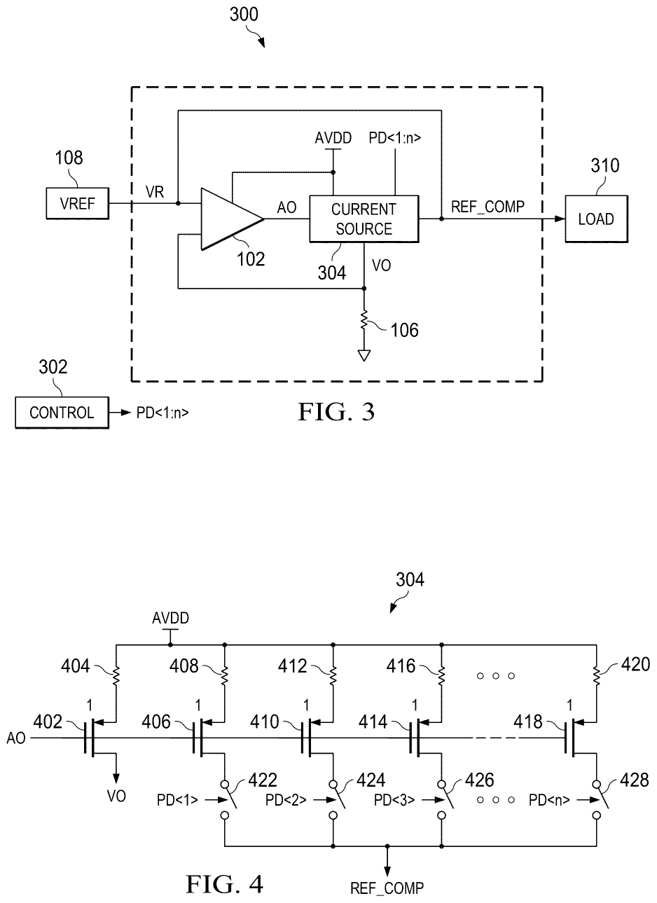

FIG. 3 is a block diagram of an example current boost circuit 300. The current boost circuit 300 is similar to the current boost circuit 100, and includes circuitry to enable the REF_COMP current to be varied. The current boost circuit 300 includes the amplifier 102, the resistor 106, and a current source 304. As described with reference to the current boost circuit 100, the amplifier 102 has first and second inputs, and an output. The first input of the amplifier 102 is coupled to an output of a voltage reference circuit voltage reference circuit 108. The second input of the amplifier 102 is coupled to a first output of the current source 304, and an output of the amplifier 102 is coupled to an input of the current source 304. The amplifier 102 controls the current source 304 based on the voltage (VR) provided by the voltage reference circuit 108. The current source 304 has a voltage terminal that is coupled to a supply voltage terminal (AVDD). The current source 304 draws current from AVDD to support VR provided to a load circuit 310. In some examples, the current boost circuit 300 and the load circuit 310 may be provided on a same integrated circuit, and in other examples on different integrated circuits. The voltage reference circuit 108 may be coupled to the current boost circuit 300 and the load circuit 310 using a terminal (e.g., a pin, pad, lead, etc.) of the integrated circuit.

The current source 304 has a first input coupled to the output of the amplifier 102 for receipt of amplifier output signal AO, a first output coupled to the second input of the amplifier 102, and a second output coupled to a reference voltage input of the load circuit 310 and to the first input of the amplifier 102 (to the output of the voltage reference circuit 108). The resistor 106 has a first terminal coupled to the first output of the current source 304, and a second terminal coupled to a reference terminal (e.g., ground). The current source 304 provides a first current at the first output, as signal VO. The first current provided at the first output of the current source 304 flows through the resistor 106, and the amplifier 102 causes the voltage across the resistor 106 to be the same as the voltage VR provided by the voltage reference circuit 108. The resistance of the resistor 106 may be selected to draw a quantity of the first current equal to a selected fraction of the current drawn at the reference voltage input of the load circuit 310.

The current source 304 provides a current (REF_COMP) at its second output. REF_COMP current may be a selected multiple (e.g., 4, 8, 16, 32, etc.) of the current provided at the first output of the current source 304. For example, REF_COMP may be selected to equal the current drawn at the reference voltage input of the load circuit 310. The voltage reference circuit 108 controls the voltage at the second output of the current source 304, while the current drawn by the reference voltage input of the load circuit 310 is provided, in large part or in whole, by the current source 304. Accordingly, the current boost circuit 300 can significantly reduce the current drawn from the voltage reference circuit 108.

The current source 304 has a second input (a selection input) that enables the REF_COMP current to be selected based on the control signals PD<1:n>. For example, a first value of PD<1:n>may cause the current source 304 to provide a first (e.g., lower) value of REF_COMP current, and a second value of PD<1:n>may cause the current source 304 to provide a second (e.g., higher) value of REF_COMP current. In some examples of the current source 304, the different values of REF_COMP current may be different multiples of the VO current. The current sink capability of the voltage reference circuit 108 may be limited because the voltage reference circuit 108 is intended to source current. Selection of REF_COMP current allows the current boost circuit 300 to provide sufficient current to the load circuit 310, while reducing the current that the voltage reference circuit 108 must sink to control the reference voltage. A control circuit 302 may provide PD<1:n>based on the circuitry of the load circuit 310 that is enabled (e.g., enabled via a user interface) to draw current from the reference input of the load circuit 310.

FIG. 4 is a schematic diagram of an example current source 304 with variable current output suitable for use in the current boost circuit 300. The current source 304 includes transistors 402, 406, 410, 414, and 418, resistors 404, 408, 412, 416, and 420, and switches 422, 424, 426, and 428. The transistors 406, 410, 414, and 418 may be sized the same as or different than the transistor 402. Some examples of the current source 304 may include more or fewer switches and corresponding transistors than are shown in FIG. 4. In the current source 304, PD<1:n>control the switches 422, 424, 426, and 428 to adjust the REF_COMP current. The transistor 402 has a first terminal (e.g., source) coupled to AVDD by the resistor 404. The resistor 404 has a first terminal coupled to AVDD and a second terminal coupled to the first terminal of the transistor 402. The transistor 402 has a second terminal (e.g., drain) that serves as the first output of the current source 304. VO is provided at the second terminal of the transistor 402. The transistor 402 has a control terminal (e.g., gate) coupled to the output of the amplifier 102.

The transistor 406 has a first terminal (e.g., source) coupled to AVDD by the resistor 408. The resistor 408 has a first terminal coupled to AVDD and a second terminal coupled to the first terminal of the transistor 406. The transistor 406 has a second terminal (e.g., drain) coupled to the switch 422, and a control terminal (e.g., gate) coupled to the output of the amplifier 102. The switch 422 has a first terminal coupled to second terminal of the transistor 406, a second terminal coupled to the second output of the current source 304, and a control input coupled to the second input of the current source 304. The switch 422 can be opened or closed based on PD<1:n>(or a subset thereof) to enable or disable current flow through the transistor 406 to the second output of the current source 304.

The transistor 410 has a first terminal (e.g., source) coupled to AVDD by the resistor 412. The resistor 412 has a first terminal coupled to AVDD and a second terminal coupled to the first terminal of the transistor 410. The transistor 410 has a second terminal (e.g., drain) coupled to the switch 424, and a control terminal (e.g., gate) coupled to the output of the amplifier 102. The switch 424 has a first terminal coupled to second terminal of the transistor 410, a second terminal coupled to the second output of the current source 304, and a control input coupled to the second input of the current source 304. The switch 424 can be opened or closed based on PD<1:n>(or a subset thereof) to enable or disable current flow through the transistor 410 to the second output of the current source 304.

The transistor 414 has a first terminal (e.g., source) coupled to AVDD by the resistor 416. The resistor 416 has a first terminal coupled to AVDD and a second terminal coupled to the first terminal of the transistor 414. The transistor 414 has a second terminal (e.g., drain) coupled to the switch 426, and a control terminal (e.g., gate) coupled to the output of the amplifier 102. The switch 426 has a first terminal coupled to second terminal of the transistor 414, a second terminal coupled to the second output of the current source 304, and a control input coupled to the second input of the current source 304. The switch 426 can be opened or closed based on PD<1:n>(or a subset thereof) to enable or disable current flow through the transistor 414 to the second output of the current source 304.

The transistor 418 has a first terminal (e.g., source) coupled to AVDD by the resistor 420. The resistor 420 has a first terminal coupled to AVDD and a second terminal coupled to the first terminal of the transistor 418. The transistor 418 has a second terminal (e.g., drain) coupled to the switch 428, and a control terminal (e.g., gate) coupled to the output of the amplifier 102. The switch 428 has a first terminal coupled to second terminal of the transistor 418, a second terminal coupled to the second output of the current source 304, and a control input coupled to the second input of the current source 304. The switch 428 can be opened or closed based on PD<1:n>(or a subset thereof) to enable or disable current flow through the transistor 418 to the second output of the current source 304.

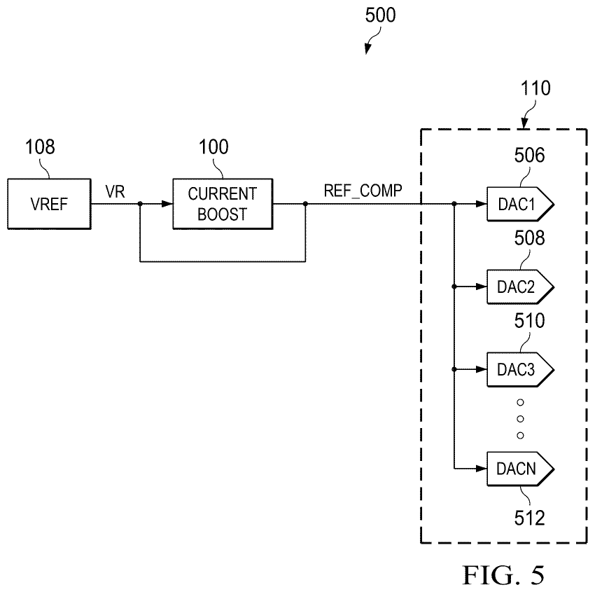

FIG. 5 is a block diagram of an example system 500 that uses a reference voltage with current boosting as described herein. The system 500 includes the current boost circuit 100, the voltage reference circuit 108, and the load circuit 110. The output of the voltage reference circuit 108 is coupled to the input of the current boost circuit 100 and the reference voltage input of the load circuit 110. The REF_COMP output of the current boost circuit 100 is also coupled to the reference voltage input of the load circuit 110. The load circuit 110 includes multiple DACs. Examples of the load circuit 110 may include one or more DACs. For example, the load circuit 110 may include 16 DACs, 32 DACs, etc. In FIG. 5, the load circuit 110 includes DACs 506, 508, 510, and 512. Each of the DACs has a reference input coupled to the reference voltage input of the load circuit 110. Each DAC uses the reference voltage provided by the voltage reference circuit 108, and draws current from the reference voltage input of the load circuit 110. The greater the number of DACs, the higher the current drawn from the reference voltage input of the load circuit 110. The current boost circuit 100 provides REF_COMP as described herein to reduce the current drawn from the voltage reference circuit 108, and enable the voltage reference circuit 108 to regulate the desired reference voltage.

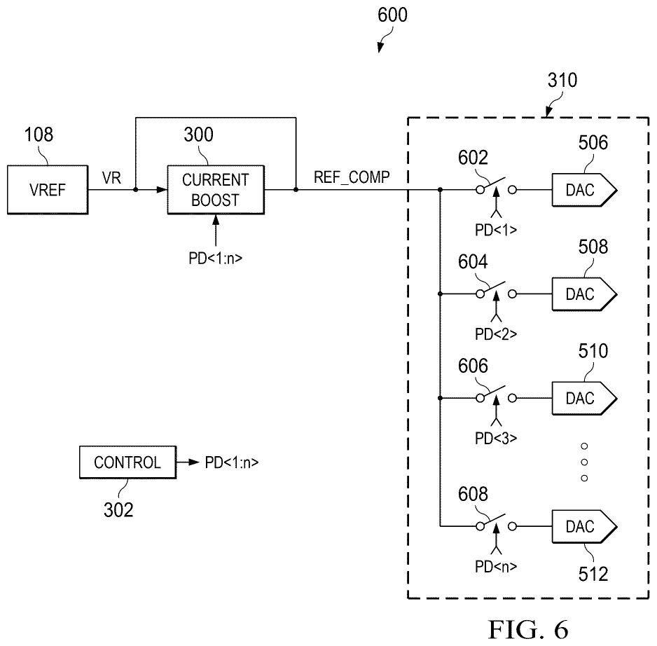

FIG. 6 is a block diagram of an example system 600 that uses a reference voltage with current boosting as described herein. The system 600 includes the current boost circuit 300, the voltage reference circuit 108, the load circuit 310, and the control circuit 302. The output of the voltage reference circuit 108 is coupled to the input of the current boost circuit 300 and the reference voltage input of the load circuit 310. The REF_COMP output of the current boost circuit 300 is also coupled to the reference voltage input of the load circuit 310. The load circuit 310 includes multiple DACs. Examples of the load circuit 310 may include one or more DACs. For example, the load circuit 310 may include 16 DACs, 32 DACs, etc. In FIG. 5, the current boost circuit 100 includes DACs 506, 508, 510, and 512. Each of the DACs uses the reference voltage provided by the voltage reference circuit 108, and draws current from the reference voltage input of the load circuit 310. The greater the number of DACs, the higher the current drawn from the reference voltage input of the load circuit 310.

Each DAC of the load circuit 310 is coupled to the reference voltage input of the load circuit 310 by a switch. The DACs 506, 508, 510 and 512 are coupled to the reference voltage input of the load circuit 310 by switches 602, 604, 606, and 608, respectively. The switches 602, 604, 606, and 608 have control inputs that are coupled to the control circuit 302 (or to a DAC selection terminal providing PD<1:n>) for receipt of PD<1:n>. Accordingly, each of the DACs 506, 508, 510 and 512 can be connected/disconnected from the reference voltage input of the load circuit 310 by the switches 602, 604, 606, and 608. If disconnected from the reference voltage input, a DAC may be powered down to reduce the power consumed by the load circuit 310. The current drawn by the DACs from the reference voltage input of the load circuit 310 increases or decreases based on the number of the switches 602, 604, 606, and 608 that are closed.

The current boost circuit 300 is also coupled to the control circuit 302 for receipt of PD<1:n>. As explained with regard to FIG. 4, switches of the current source 304 enable REF_COMP current flow responsive to PD<1:n>. Accordingly, the REF_COMP current may be selected based on the number of DACs of the load circuit 310 that are drawing current from the reference input of the load circuit 310. In this way, the current boost circuit 300 provides sufficient current for the enabled DACs, while reducing the current that the voltage reference circuit 108 sinks to regulate the reference voltage.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) (n-type transistor) or a p-channel FET (PFET) ) (p-type transistor)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input (or transistor control terminal) is the gate, and the current terminals are the drain and source. In the context of a BJT, the control input is the base, and the current terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An apparatus comprising:
an amplifier having a voltage reference input, a second input, an output, and a terminal coupled to a supply voltage terminal; and
a current source having an input coupled to the output of the amplifier, a first output coupled to the second input of the amplifier, a second output coupled to the voltage reference input of the amplifier, and a terminal coupled to the supply voltage terminal.

2. The apparatus of claim 1, further comprising a resistor having a first terminal coupled to the first output of the current source and the second input of the amplifier, and a second terminal coupled to a reference terminal.

3. The apparatus of claim 2, wherein the current source includes:
a first transistor having a first terminal, a second terminal coupled to the first output of the current source, and a control terminal coupled to the input of the current source;
a first resistor having a first terminal coupled to the first terminal of the first transistor, and a second terminal coupled to the supply voltage terminal;
a second transistor having a first terminal, a second terminal coupled to the second output of the current source, and a control terminal coupled to the input of the current source; and
a second resistor having a first terminal coupled to the first terminal of the second transistor, and a second terminal coupled to the supply voltage terminal.

4. The apparatus of claim 3, further comprising a voltage reference circuit having an output coupled to the voltage reference input of the amplifier.

5. The apparatus of claim 4, further comprising:
a first digital-to-analog converter (DAC) having a reference input coupled to the output of the voltage reference circuit and the second terminal of the second transistor; and
a second DAC having a reference input coupled to the output of the voltage reference circuit and the second terminal of the second transistor.

6. The apparatus of claim 4, wherein the current source has a second input and further includes:
a first switch having a first terminal coupled to the second terminal of the second transistor, a second terminal coupled to the second output of the current source, and a control input coupled to the second input of the current source;
a third transistor having a first terminal, a second terminal coupled to the second output of the current source, and a control terminal coupled to the input of the current source;
a third resistor having a first terminal coupled to the first terminal of the third transistor, and a second terminal coupled to the supply voltage terminal; and
a second switch having a first terminal coupled to the second terminal of the third transistor, a second terminal coupled to the second output of the current source, and a control input coupled to the second input of the current source.

7. The apparatus of claim 6, further comprising:
a first DAC having a reference input;
a third switch having a first terminal coupled to the reference input of the first DAC, a second terminal coupled to the second output of the current source, and a control terminal coupled to a DAC selection terminal;
a second DAC having a reference input; and
a fourth switch having a first terminal coupled to the reference input of the second DAC, a second terminal coupled to the second output of the current source, and a control terminal coupled to the DAC selection terminal.

8. An apparatus comprising:
an amplifier having a voltage reference input, a second input, an output, and a terminal coupled to a supply voltage terminal; and
a current source including:
a first transistor having a first terminal coupled to the supply voltage terminal, a second terminal coupled to the second terminal of the amplifier, and a control terminal coupled to the output of the amplifier; and
a second transistor having a first terminal coupled to the supply voltage terminal, a second terminal coupled to the voltage reference input of the amplifier, and a control terminal coupled to the output of the amplifier.

9. The apparatus of claim 8, further comprising a voltage reference circuit having an output coupled to the voltage reference input of the amplifier.

10. The apparatus of claim 9, further comprising:
a first DAC having a reference input coupled to the output of the voltage reference circuit and the second terminal of the second transistor; and
a second DAC having a reference input coupled to the output of the voltage reference circuit and the second terminal of the second transistor.

11. The apparatus of claim 10, further comprising:
a resistor having a first terminal coupled to the second terminal of the first transistor and the second input of the amplifier, and a second terminal coupled to a reference terminal;
wherein the current source includes:
a first resistor having a first terminal coupled to the supply voltage terminal, and a second terminal coupled to the first terminal of the first transistor; and
a second resistor having a first terminal coupled to the supply voltage terminal, and a second terminal coupled to the first terminal of the second transistor.

12. The apparatus of claim 10, wherein the current source has a control input and further includes:
a first switch having a first terminal coupled to the second terminal of the second transistor, a second terminal coupled to the voltage reference input of the amplifier, and a control input coupled to the control input of the current source;
a third transistor having a first terminal coupled to the supply voltage terminal, a second terminal, and a control terminal coupled to the output of the amplifier; and
a second switch having a first terminal coupled to the second terminal of the third transistor, a second terminal coupled to the voltage reference input of the amplifier, and a control input coupled to the control input of the current source.

13. The apparatus of claim 12, wherein the current source includes:
a first resistor having a first terminal coupled to the supply voltage terminal, and a second terminal coupled to the first terminal of the first transistor; and
a second resistor having a first terminal coupled to the supply voltage terminal, and a second terminal coupled to the first terminal of the second transistor, and
a third resistor having a first terminal coupled to the supply voltage terminal, and a second terminal coupled to the first terminal of the third transistor.

14. The apparatus of claim 12, further comprising:
a third switch having a first terminal coupled to the reference input of the first DAC, a second terminal coupled to the second terminal of the first switch, and a control terminal coupled to a DAC selection terminal; and
a fourth switch having a first terminal coupled to the reference input of the second DAC, a second terminal coupled to the second terminal of the second switch, and a control terminal coupled to the DAC selection terminal.

15. A system comprising:
a digital-to-analog converter (DAC) having a reference input; and
a current boost circuit including:
an amplifier having a voltage reference input, a second input, an output, and a terminal coupled to a supply voltage terminal;
a resistor having a first terminal coupled to the second input of the amplifier, and a second terminal coupled to a reference terminal; and
a current source including:
a first transistor having a first terminal coupled to the supply voltage terminal, a second terminal coupled to the second input of the amplifier, and a control terminal coupled to the output of the amplifier; and
a second transistor having a first terminal coupled to the supply voltage terminal, a second terminal coupled to the voltage reference input of the amplifier and the reference input of the DAC, and a control terminal coupled to the output of the amplifier.

16. The system of claim 15, wherein the current boost circuit includes:
a first resistor having a first terminal coupled to the supply voltage terminal, and a second terminal coupled to the first terminal of the first transistor; and
a second resistor having a first terminal coupled to the supply voltage terminal, and a second terminal coupled to the first terminal of the second transistor.

17. The system of claim 15, wherein the current source has a control input and further includes:
a first switch having a first terminal coupled to the second terminal of the second transistor, a second terminal coupled to the reference input of the DAC, and a control input coupled to the control input of the current source;
a third transistor having a first terminal, a second terminal, and a control terminal coupled to the output of the amplifier;
a third resistor having a first terminal coupled to the supply voltage terminal, and a second terminal coupled to the first terminal of the third transistor; and
a second switch having a first terminal coupled to the second terminal of the third transistor, a second terminal coupled to the reference input of the DAC, and a control input coupled to the control input of the current source.

18. The system of claim 17, further comprising a voltage reference circuit having an output coupled to the reference input of the DAC and the voltage reference input of the amplifier.

19. The system of claim 15, wherein the DAC is a first DAC, and the system further comprising:
a second DAC having a reference input;
a first switch having a first terminal coupled to the reference input of the first DAC, a second terminal coupled to the second terminal of the second transistor, and a control terminal coupled to a DAC selection terminal;
a second switch having a first terminal coupled to the reference input of the second DAC, a second terminal coupled to the second terminal of the second transistor, and a control terminal coupled to the DAC selection terminal; and
a voltage reference circuit having an output coupled to the reference input of the first DAC, the reference input of the second DAC, and the voltage reference input of the amplifier.

20. The system of claim 19, wherein the current source has a control input and further includes:
a third switch having a first terminal coupled to the second terminal of the second transistor, a second terminal coupled to the second terminal of the first switch, and a control input coupled to the control input of the current source;
a third transistor having a first terminal, a second terminal, and a control terminal coupled to the output of the amplifier; and
a fourth switch having a first terminal coupled to the second terminal of the third transistor, a second terminal coupled to the second terminal of the second switch, and a control input coupled to the control input of the current source.
